(19) United States
(12) Patent Application Publication
(10) Pub. No.: US 2026/0134903 A1
(43) Pub. Date: May 14, 2026

(54) METHOD FOR CALIBRATION, INTEGRATED CIRCUIT AND MEMORY DEVICE INCLUDING THE SAME

(71) Applicant: Samsung Electronics Co., Ltd., Suwon-si (KR)

(72) Inventors: Cheolmin Ahn, Suwon-si (KR); Jaewoo Lee, Suwon-si (KR); Kihan Kim, Suwon-si (KR); Daesik Moon, Suwon-si (KR)

(21) Appl. No.: 19/184,282

(22) Filed: Apr. 21, 2025

(30) Foreign Application Priority Data
Nov. 11, 2024 (KR) 10-2024-0158979

(51) Int. Cl. G11C 11/4076

(52) U.S. Cl. CPC G11C 11/4076

(57) ABSTRACT

A method for calibration, an integrated circuit and a memory device are provided. A method for calibration comprises outputting a second data clock obtained by compensating for a first data clock based on a calibration signal and a first voltage, outputting a first pulse based on the first and second data clocks, updating a control signal based on a reference voltage generated based on the control signal and the first pulse, outputting a third data clock obtained by compensating for the first data clock based on the calibration signal and a second voltage less than the first voltage, outputting a second pulse based on the first and third data clocks, and updating the calibration signal based on the reference voltage generated based on the control signal that was updated and the second pulse.

### CROSS REFERENCE TO RELATED APPLICATION

This application claims priority from Korean Patent Application No. 10-2024-0158979 filed on Nov. 11, 2024, in the Korean Intellectual Property Office and all the benefits accruing therefrom under 35 U.S.C. 119, the contents of which in its entirety are herein incorporated by reference.

### BACKGROUND

The present invention relates to a method for calibration, an integrated circuit, and a memory device including the same.

A memory device receives signals such as commands, addresses, and data from outside of a memory and processes them. In the process of receiving and storing data from the outside and outputting the data to the outside, the memory device samples the data in accordance with a data clock. At this time, a delay may occur in the data clock on the data clock path, which is a path through which the data clock is transmitted inside the memory device.

The memory device may be supplied with a power supply voltage required for operation from the outside. However, the magnitude of the received power supply voltage may not be kept constant due to a reason such as noise. Depending on the fluctuation of the power supply voltage received by the data clock path, a magnitude difference of the delay occurring in the data clock may occur. Therefore, a compensation circuit, which may compensate for the magnitude difference of the delay that occurs in the data clock depending on the fluctuation of the power supply voltage, is present on the data clock path. However, there may be a difference in the degree of compensation for each memory device due to the reason such as a difference in sensitivity to the power supply voltage for each memory device.

### SUMMARY

Aspects of the present invention provide a method for calibration.

Aspects of the present invention also provide an integrated circuit capable of performing the method for calibration.

Aspects of the present invention also provide a memory device to which an integrated circuit capable of performing the method for calibration is applied.

According to some embodiments of present disclosure, there is provided a method for calibration comprises outputting a second data clock obtained by compensating for a first data clock based on a calibration signal and a first voltage, outputting a first pulse based on the first and second data clocks, updating a control signal based on a reference voltage generated based on a control signal and the first pulse, outputting a third data clock obtained by compensating for the first data clock based on the calibration signal and a second voltage less than the first voltage, outputting a second pulse based on the first and third data clocks, and updating the calibration signal based on the reference voltage generated based on the control signal that was updated and the second pulse.

According to some embodiments of present disclosure, there is provided an integrated circuit comprises a data clock path circuit that is configured to receive a first voltage, a first data clock, and a calibration signal, and is configured to compensate for a delay of the first data clock using the first voltage in accordance with the calibration signal to output a second data clock, a comparison circuit configured to output a first pulse based on the first data clock and the second data clock, a reference voltage generation circuit configured to receive a control signal, and configured to output a reference voltage in accordance with the control signal, and a duty cycle monitor configured to compare a magnitude of the reference voltage with a duty cycle of the first pulse, and configured to output a first comparison signal corresponding to a result of comparing the magnitude of the reference voltage with the duty cycle of the first pulse.

According to some embodiments of present disclosure, there is provided a memory device comprises a memory cell array configured to store data, a data clock path circuit configured to output a second data clock based on a first data clock and a first voltage, and configured to output a third data clock based on the first data clock and a second voltage less than the first voltage, a calibration circuit configured to determine a calibration signal based on the first, second and third data clocks, and a control logic circuit configured to provide the calibration signal to the data clock path circuit, wherein the data clock path circuit is configured to output a fourth data clock based on the first data clock and the calibration signal, and the control logic circuit is configured to write data to the memory cell array, using the fourth data clock.

However, aspects of the present invention are not restricted to the one set forth herein. The above and other aspects of the present invention will become more apparent to one of ordinary skill in the art to which the present invention pertains by referencing the detailed description of the present invention given below.

Specific matters of other embodiments are included in the detailed description and drawings.

### BRIEF DESCRIPTION OF THE DRAWINGS

FIG. 1 is a diagram of a memory system, according to some embodiments.

FIG. 2 is a block diagram of the memory device of FIG. 1.

FIG. 3 is a block diagram of the data clock, according to some embodiments.

FIG. 4 is a graph of signals associated with the data clock, according to some embodiments.

FIG. 5 is a block diagram of a circuit that implements a method for compensating for the delay of the data clock, according to some embodiments.

FIG. 6 is a graph of operations of a method for compensating for the delay of the data clock, according to some embodiments.

FIG. 7 is a block diagram of a calibration circuit according to some embodiments.

FIG. 8 is a flowchart of a method for calibration according to some embodiments.

FIG. 9 is a block diagram of a circuit implementing the method for calibration according to some embodiments.

FIG. 10 is a graph of signals of the method for calibration according to some embodiments.

FIG. 11 is a diagram of a circuit for implementing the method for calibration according to some embodiments.

FIG. 12 is a graph of signals of the method for calibration according to some embodiments.

FIG. 13 is a flowchart of the method for calibration according to some embodiments.

FIG. 14 is a flowchart of a method for calibration according to some embodiments.

FIG. 15 is a block diagram of an electronic device including a memory device to which the calibration circuit according to some embodiments is applied.

### DETAILED DESCRIPTION OF THE EMBODIMENTS

Hereinafter, embodiments according to the technical idea of the present invention will be described referring to the attached drawings. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification.

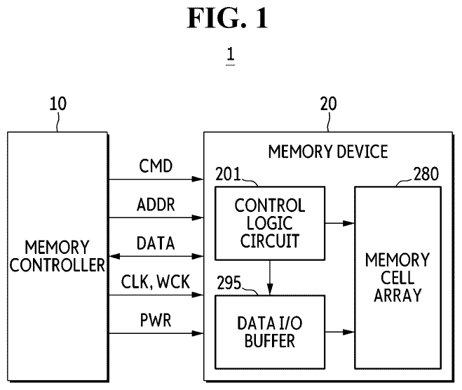

FIG. 1 is a diagram of a memory system.

Referring to FIG. 1, the memory system 1 may include a memory device 20 and a memory controller 10.

The memory controller 10 may control the overall operation of the memory device 20. For example, the memory controller 10 may control a data exchange between the outside and the memory device 20. For example, the memory controller 10 may control the memory device 20 in accordance with an external request, and may write data or read data therethrough.

The memory controller 10 and the memory device 20 may communicate with each other through a memory interface. Also, the memory controller 10 and the host may communicate with each other through a host interface. That is, the memory controller 10 may mediate signals between the memory device 20 and the host. The memory controller 10 may control the operation of the memory device 20 by applying a command CMD for controlling the memory device 20. Here, the memory device 20 may include dynamic memory cells. For example, the memory device 20 may include a dynamic random access memory (DRAM), a double data rate 4 (DDR4) a synchronous DRAM (DDR4), a DDR5 SDRAM, a low power DDR4 (LPDDR4) SDRAM, a LPDDR5 SDRAM or the like. However, embodiments according to the technical idea of the present invention are not limited thereto, and the memory device 20 may include a non-volatile memory device. However, in the present embodiments, the memory device 20 will be described as being a volatile memory device.

The memory controller 10 may transmit a system clock CLK, a data clock WCK, a command CMD, an address ADDR, power PWR, and the like to the memory device 20. The memory controller 10 may provide data DATA to the memory device 20, and may receive data DATA from the memory device 20. The memory device 20 may include a memory cell array 280 in which data DATA is stored, a control logic circuit 201, a data input/output buffer 295, and the like.

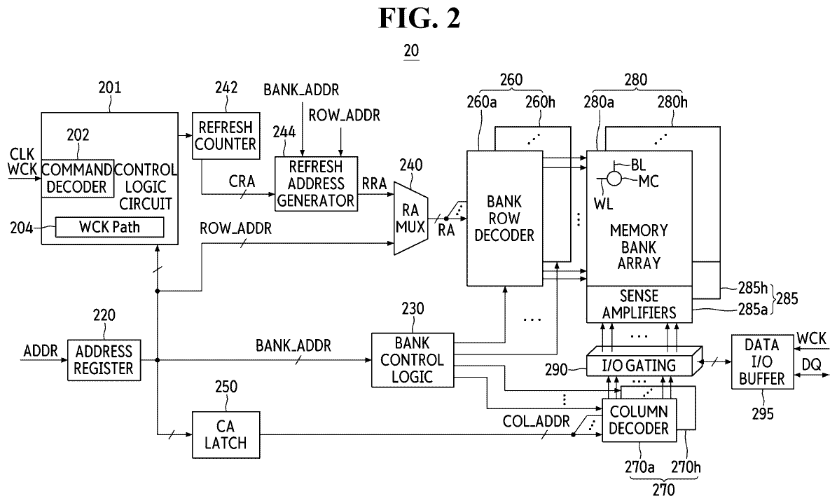

FIG. 2 is a block diagram of the memory device of FIG. 1.

Referring to FIG. 2, the memory device 20 may include a control logic circuit 201, an address register 220, a bank control logic circuit 230, a row address multiplexer 240, a refresh counter 242, a refresh address generator 244, a column address latch 250, a row decoder 260, a column decoder 270, a memory cell array 280, a sense amplifier unit 285, an input/output gating circuit 290, and a data input/output buffer 295.

The memory cell array 280 may include a plurality of memory bank arrays 280a to 280h. Although the memory bank array 280 is shown to include eight memory bank arrays 280a to 280h in FIG. 2, the embodiments are not limited thereto.

Each of the plurality of memory bank arrays 280a to 280h may include a plurality of word lines WL, a plurality of bit lines BL, and a plurality of memory cells MC formed at the intersections between the word lines WL and the bit lines BL.

The row address multiplexer 240 may include a plurality of bank row decoders 260a to 260h each electrically connected to the plurality of memory bank arrays 280a to 280h. The column decoder 270 may include a plurality of column decoders 270a to 270h each electrically connected to the plurality of memory bank arrays 280a to 280h. The sense amplifier unit 285 may include a plurality of sense amplifiers 285a to 285h each electrically connected to the plurality of memory bank arrays 280a to 280h.

The address register 220 may receive an address ADDR including a bank address BANK_ADDR, a row address ROW_ADDR, and a column address COL_ADDR from the memory controller (20 of FIG. 1). The address register 220 may provide the received bank address BANK_ADDR to the bank control logic circuit 230, provide the received row address ROW_ADDR to the row address multiplexer 240, and provide the received column address COL_ADDR to the column address latch 250.

The bank control logic circuit 230 may generate bank control signals in response to the bank address BANK_ADDR. In response to the bank control signals, a bank row decoder corresponding to the bank address BANK_ADDR among the plurality of bank row decoders 260a to 260h may be activated, and a column decoder corresponding to the bank address BANK_ADDR among the plurality of column decoders 270a to 270h may be activated.

The refresh counter 242 may sequentially output counting row addresses CRA in accordance with the control of the control logic circuit 201. For example, the control logic circuit 201 may generate a refresh count signal in response to a normal refresh command. The refresh counter 242 may perform a counting operation in response to the refresh count signal, and output a counting row address CRA. That is, the refresh counter 242 may output a refresh address for performing a normal refresh operation.

The refresh address generator 244 may be provided with the bank address BANK_ADDR and the row address ROW_ADDR. The refresh address generator 244 may count values at which the bank address BANK_ADDR and the row address ROW_ADDR are activated on the basis of the bank address BANK_ADDR and the row address ROW_ADDR. The refresh address generator 244 may generate a row address corresponding to a word line that is activated a certain number of times or more on the basis of the counted value, or a row address corresponding to a word line adjacent to the word line as a hammer address. That is, the refresh address generator 244 may output a refresh address for performing a target row refresh operation.

The refresh address generator 244 may output either the counting row address CRA or the hammer address as the refresh row address RRA.

The refresh counter 242 and the refresh address generator 244 may be implemented as separate configurations as shown, or the refresh counter 242 and the refresh address generator 244 may be implemented as a single configuration. Also, the refresh counter 242 and the refresh address generator 244 may be implemented to be included in the control logic circuit 201.

The row address multiplexer 240 may receive the row address ROW_ADDR from the address register 220, and receive the refresh row address RRA from the refresh address generator 244. The row address multiplexer 240 may selectively output the row address ROW_ADDR or the refresh row address RRA as the row address RA. The row address RA that is output from the row address multiplexer 240 may be applied to each of the plurality of bank row decoders 260a to 260h.

Among the plurality of bank row decoders 260a to 260h, the bank row decoder activated by the bank control logic circuit 230 may decode the row address RA which is output from the row address multiplexer 240 to activate the word line corresponding to the row address. For example, the activated bank row decoder may apply a word line driving voltage to a word line corresponding to the row address.

The column address latch 250 may receive the column address COL_ADDR from the address register 220, and temporarily store the received column address COL_ADDR. The column address latch 250 may gradually increase the received column address COL_ADDR in a burst mode. The column address latch 250 may apply the temporarily stored or gradually increased column address COL_ADDR to each of the plurality of column decoders 270a to 270h.

Among the plurality of column decoders 270a to 270h, the bank column decoders activated by the bank control logic circuit 230 may activate the sense amplifier corresponding to the bank address BANK_ADDR and the column address COL_ADDR through the corresponding input/output gating circuit 290.

The input/output gating circuit 290 may include an input data mask logic, reading data latches for storing data that are output from the plurality of memory bank arrays 280a to 280h, and write drivers for writing the data to the plurality of memory bank arrays 280a to 280h, together with circuits for gating the input/output data.

The data DQ to be read from one bank array among the plurality of memory bank arrays 280a to 280h may be detected by one of the sense amplifiers 285a to 285h corresponding to the one bank array, and stored in the reading data latches. The data DQ stored in the reading data latches may be synchronized with the data clock WCK through the data input/output buffer 295, and provided to the memory controller 10.

Data DQ to be written to one bank array among the plurality of memory bank arrays 280a to 280h is synchronized with the data clock WCK through the data input/output buffer 295 and provided to the input/output gating circuit 290, and the input/output gating circuit 290 may write the data to one of the bank arrays through the write drivers.

The control logic circuit 201 may control the operation of the memory device 20. For example, the control logic circuit 201 may generate control signals so that the memory device 20 performs a write operation or a read operation. The control logic circuit 201 may include a command decoder 202 that decodes the command CMD received from the memory controller 10.

According to some embodiments, the control logic circuit 201 may further include a data clock path (WCK path) 204 (also referred to as a data clock path circuit). Although the data clock path 204 is shown to be included in the control logic circuit 201 in FIG. 2, the data clock path 204 may be configured separately from the control logic circuit 201 according to embodiments of the present invention. The control logic circuit 201 may receive a system clock CLK and a data clock WCK from the memory controller 10. The system clock CLK may be a clock for processing the command CMD and the address ADDR. The data clock WCK may be a clock for processing the data DATA. A delay may occur in the data clock WCK while the data clock WCK passes through the data clock path 204 of the memory device 20. Thus, the data clock path 204 may reduce the effect of the delay, by including a compensation circuit that may compensate for the delayed data clock WCK.

The memory cells MC may be, for example, DRAM memory cells. The memory cells MC may be connected to each of one word line WL and one bit line BL. The memory cells MC may store charges through a cell capacitor. The memory cells MC may erase data stored in the cell capacitor because a leakage current occurs due to the structure of the memory cells MC. Thus, the memory device 20 may perform a refresh operation for recharging data in the memory cells MC to prevent data stored in the memory cells MC from being changed by the leakage current.

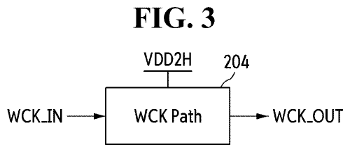

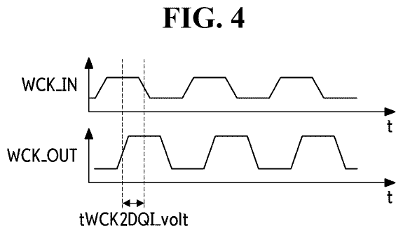

FIG. 3 is a block diagram of the data clock. FIG. 4 is a graph of signals associated with the data clock. In FIG. 4, an x-axis of the two graphs represents time, and a y-axis of the two graphs represents a logical value of the signal. For example, a state in which the magnitude of the signal is relatively large may be called logic-high, and a state in which the magnitude of the signal is relatively small may be called logic-low.

Referring to FIGS. 3 and 4, the memory device may receive an input data clock WCK_IN from the outside (e.g., a memory controller). The received data clock WCK_IN may be transmitted along a data clock path 204. The data clock path 204 may include various circuits and wirings, and a delay may occur in the data clock WCK_IN as the data clock WCK_IN is transmitted along the path.

The memory device may be provided with power supply voltages required for various operations of the memory device from the outside (e.g., a memory controller). For example, LPDDR5 SDRAM may be provided with power supply voltages such as VDD1, VDD2H, VDD2L, and VDDQ, which are specified in a JEDEC specification for LPDDR5 SDRAM. The data clock path 204 may output an output data clock WCK_OUT, and the data clock WCK_OUT that is output by the data clock path 204 may be a clock in which a delay occurs (having a delayed phase) in the data clock WCK_IN which is input to the data clock path 204. The data clock WCK_OUT which is output by the data clock path 204 may reduce the reading and writing performance margin of data.

The data clock path 204 may be provided with, for example, a first power supply voltage VDD2H and may output the data clock WCK_OUT by using the same. Incidentally, the first power supply voltage VDD2H received by the data clock path 204 may be unstable due to reasons such as a noise. As a result, the memory device may not be constantly supplied with a power supply voltage having a magnitude of a specified operating voltage (for example, 1.05V in the case of VDD2H of the JEDEC specification), and may receive a power supply voltage that is smaller or larger than (i.e., less than or greater than) the specified operating voltage at a particular moment. The higher the first power supply voltage VDD2H received by the data clock path 204 is, the faster the circuit operates. Accordingly, the delay of the data clock WCK_OUT which is output by the data clock path 204 may decrease. In contrast, the lower the first power supply voltage VDD2H received by the data clock path 204 is, the slower the circuit operates. Accordingly, the delay of the data clock WCK_OUT which is output by the data clock path 204 may increase. The difference in delay of the data clock due to the fluctuation of the power supply voltage (e.g., the first power supply voltage VDD2H) is specified as tWK2DQI_volt in the JEDEC specification.

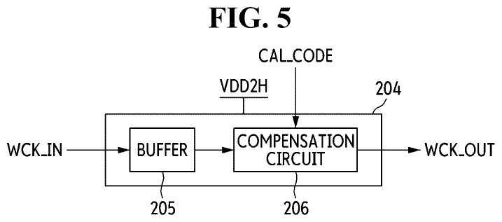

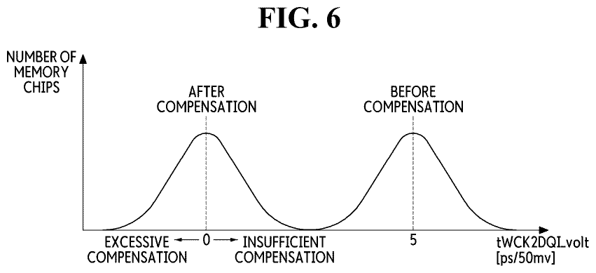

FIG. 5 is a block diagram of a circuit that implements a method for compensating for the delay of the data clock. FIG. 6 is a graph of operations of a method for compensating for the delay of the data clock. An x-axis of the graph of FIG. 6 represents the magnitude of the delay that occurs in the data clock by comparing the input data clock WCK_IN with the output data clock WCK_OUT, and a y-axis of the graph represents the number of memory devices. For convenience of explanation, the magnitude of the delay of the data clock WCK will be represented as tWCK2DQI_volt specified in the JEDEC specification. However, the embodiments are not limited thereto. In this example, tWCK2DQI_volt has a unit of [ps/50 mV], which means that a delay of lps occurs for each difference of 50 mV in the power supply voltage.

Referring to FIGS. 5 and 6, the data clock path 204 may include a buffer 205 and a compensation circuit 206. The buffer 205 may be, for example, various circuits included in the data clock path 204. The compensation circuit 206 may compensate for the delay of the data clock that occurs in the data clock path 204 on the basis of the received calibration signal CAL_CODE. The compensation circuit 206 may be designed in various ways. For example, the compensation circuit 206 may adjust the delay that occurs in the data clock WCK, by adjusting the phase so that the delay of the data clock WCK decreases or increases. For example, on the basis of a specified operating voltage, the compensation circuit 206 may remove the delay of the data clock WCK more as the magnitude of the received power supply voltage (e.g., the first power supply voltage VDD2H) is small, and may remove the delay of the data clock WCK less as the magnitude of the received power supply voltage (e.g., the first power supply voltage VDD2H) increases. In some embodiments, as the magnitude of the power supply voltage (e.g., the first power supply voltage VDD2H) received on the basis of the specified operating voltage is large, the delay may be added, and as the magnitude of the power supply voltage (e.g., the first power supply voltage VDD2H) received on the basis of the specified operating voltage, the delay may be removed. The design method of the compensation circuit 206 is not limited to the example described above. That is, the compensation circuit 206 may reduce a difference (tWCK2DQI_volt) in delay caused by fluctuations in the received power supply voltage. The calibration signal CAL_CODE may determine a compensation amount of the data clock depending on the magnitude of the power supply voltage received by the compensation circuit 206. In other words, the larger the magnitude of the calibration signal CAL_CODE is, the more tWKK2DQI_volt may be reduced.

When the compensation circuit 206 compensates for the data clock WCK, ideally, tWKK2DQI_volt will be zero. In other words, the delay that occurs in the data clock will not be affected by the magnitude of the first power supply voltage VDD2H. However, due to process variations (e.g., process corners) that occur in the process of the mass production of the memory devices or various other reasons, the sensitivity of each memory device to the voltage may differ for each memory device. Therefore, there may be differences in tWCK2DQI_volt for each memory device. On the basis of tWCK2DQI_volt=0 on the x-axis of the graph in FIG. 6, it means that the memory devices belonging to the left side have an excessive compensation amount of the compensation circuit 206, and the memory devices belonging to the right side have an insufficient compensation amount of the compensation circuit 206. The data read/write performance margin may be reduced not only when the compensation amount of the compensation circuit 206 is insufficient, but also when it is excessive. Therefore, in order to eliminate the variation in the tWCK2DQI_volt value for each memory device, it is necessary to determine an appropriate calibration signal CAL_CODE for each memory device.

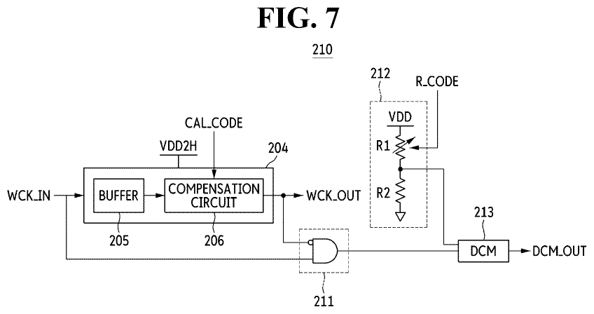

FIG. 7 is a block diagram of a calibration circuit according to some embodiments.

Referring to FIG. 7, the calibration circuit 210 may include a data clock path 204, a comparison circuit 211, a reference voltage generation circuit 212, and a duty cycle monitor (DCM) 213. The data clock path 204 may receive an input data clock WCK_IN from an external source. For example, the data clock path 204 may receive an input data clock WCK_IN from a duty cycle trimming oscillator in a memory controller or a memory device. The data clock path 204 may receive a first power supply voltage VDD2H. The buffer 205 may be, for example, various circuits included in the data clock path 204. The amount of delay occurring in the data clock may vary depending on the amount of the power supply voltage received by the data clock path 204. The compensation circuit 206 may receive a calibration signal CAL_CODE from outside (for example, the control logic circuit 201 of FIG. 1). The calibration signal CAL_CODE may determine the degree to which the compensation circuit 206 compensates for the data clock. The compensation circuit 206 may compensate for the delay of the data clock that occurs in the data clock path 204 on the basis of the received calibration signal CAL_CODE. The data clock path 204 may output the output data clock WCK in which a delay is compensated for by the compensation circuit 206.

The comparison circuit 211 receives the input data clock WCK_IN and the output data clock WCK_OUT, and may output a first pulse on the basis of the input data clock WCK_IN and the output data clock WCK_OUT. The first pulse may be, for example, a pulse that is in a logic-high state during the delayed time period of the input data clock WCK_IN and has a logic-low state otherwise. The comparison circuit 211 may be implemented using, for example, one AND gate. When the comparison circuit 211 is implemented using one AND gate, the comparison circuit 211 receives a signal obtained by inverting the input data clock WCK_IN and the output data clock WCK_OUT, and may perform an AND computation on the received signal to generate a first pulse. However, this is only an example, and the comparison circuit 211 may be implemented in various ways and configurations.

The reference voltage generation circuit 212 may include a first resistor R1 and a second resistor R2. The reference voltage generation circuit 212 may receive a second power supply voltage VDD and a control signal R_CODE. The second power supply voltage VDD may be, for example, but not limited to, one of power supply voltages such as VDD1, VDD2H, VDD2L, and VDDQ specified in the JEDEC specification of LPDDR5 SDRAM.

First resistor R1 of the reference voltage generation circuit 212 may function as variable resistor whose resistance is controlled by the control signal R_CODE. The reference voltage generation circuit 212 may adjust a resistance ratio of the first resistor R1 and the second resistor R2, for example, by adjusting the magnitude of the first resistor R1 in accordance with the control signal R_CODE. The reference voltage generation circuit 212 may generate a reference voltage in accordance with the resistance ratio of the first resistor R1 and the second resistor R2, using the second power supply voltage VDD.

The duty cycle monitor 213 may receive the reference voltage from the reference voltage generation circuit 212, and may receive a first pulse from the comparison circuit 211. The duty cycle monitor 213 may compare the duty cycle of the received first pulse with the magnitude of the reference voltage, and output a comparison signal DCM_OUT representing the comparison result. The duty cycle refers to a numerical value representing the proportion of time at which a signal is tuned on in one period of the signal. If the magnitude of the reference voltage received from the reference voltage generation circuit 212 is assumed to be 0.4V and the duty cycle of the first pulse received from the comparison circuit 211 is assumed to be 0.3, the duty cycle monitor 213 may output a logic-high signal. In contrast, if the magnitude of the reference voltage received from the reference voltage generation circuit 212 is assumed to be 0.3V and the duty cycle of the first pulse received from the comparison circuit 211 is assumed to be 0.4, the duty cycle monitor 213 may output a logic-low signal.

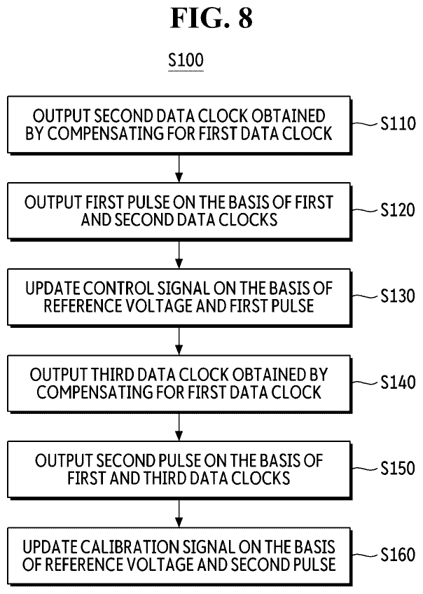

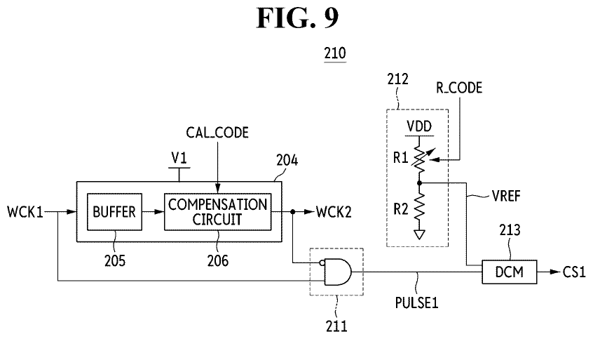

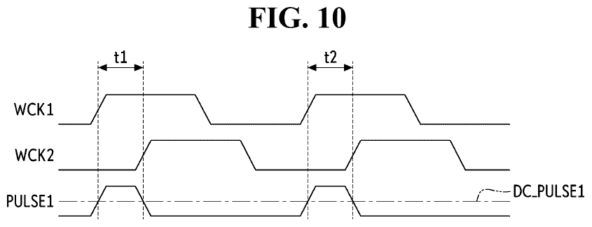

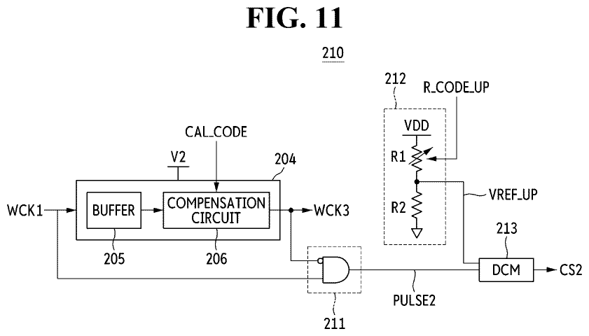

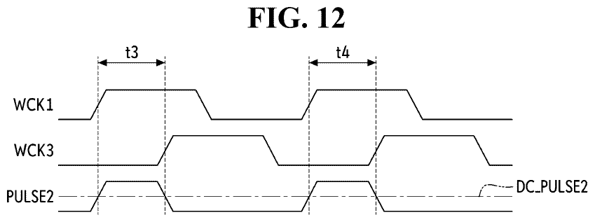

FIG. 8 is a flowchart of a method for calibration according to some embodiments. FIG. 9 is a block diagram of a circuit for implementing the method for calibration according to some embodiments. FIG. 10 is a graph of signals of the method for calibration according to some embodiments. FIG. 11 is a diagram of a circuit for implementing the method for calibration according to some embodiments. FIG. 12 is a graph of signals of the method for calibration according to some embodiments.

Referring to FIGS. 1 to 12, the method for calibration (S100) includes outputting a second data clock obtained by compensating for the first data clock (S110). For example, the data clock path 204 receives a first data clock WCK1 and a first voltage V1, and the compensation circuit 206 may output a second data clock WCK2 obtained by compensating for a delay that occurs by passing through the data clock path 204, by the use of the first voltage V1. The first voltage V1 at this time is, for example, a maximum operating voltage of VDD2H specified in the JEDEC specification, and may be, but not limited to, about 1.2 V. Prior to the operation (S110), the control logic circuit 201 may initialize the calibration signal CAL_CODE and the control signal R_CODE.

The method for calibration (S100) includes outputting a first pulse on the basis of the first and second data clocks (S120). For example, the comparison circuit 211 may receive the first data clock WCK1 and the second data clock WCK2, and output a first pulse PULSE1 on the basis of the first data clock WCK1 and the second data clock WCK2. The first pulse PULSE1 output by the comparison circuit 211 may be a pulse that is output by performing the AND computation on the signal obtained by inverting the second data clock WCK2 and the first data clock WCK1. The first pulse PULSE1 may be a pulse that is in a logic-high state during a time period (e.g., time period t1 and time period t2) at which the delay of the first data clock WCK1 occurs, and is in a logic-low state otherwise. The first pulse PULSE1 may be a pulse that is in a logic-high state while the first data clock WCK1 is in a logic-high state and the second data clock WKK2 is in a logic-low state, and is in a logic-low state otherwise.

The method for calibration (S100) includes updating the control signal on the basis of the reference voltage and the first pulse (S130). For example, the duty cycle monitor 213 may receive the reference voltage VREF according to the control signal R_CODE from the reference voltage generation circuit 212, and receive the first pulse PULSE1 from the comparison circuit 211. The duty cycle monitor 213 may compare the magnitude of the received reference voltage VREF with the duty cycle DC_PULSE1 of the first pulse PULSE1, and output a first comparison signal CS1 corresponding to the comparison result. The control logic circuit 201 may receive the first comparison signal CS1 and update the control signal R_CODE on the basis of the first comparison signal CS1. At this time, the control logic circuit 201 may update the control signal R_CODE so that the magnitude of the reference voltage VREF_UP generated on the basis of the updated control signal R_CODE_UP is equal to the duty cycle DC_PULSE1 of the first pulse PULSE1 or is greater than the duty cycle DC_PULSE1 of the first pulse PULSE1. A method for updating the control signal R_CODE will be described below.

The method for calibration (S100) includes outputting a third data clock obtained by compensating for the first data clock (S140). For example, the data clock path 204 receives the first data clock WCK1 and the second voltage V2, and the compensation circuit 206 may output a third data clock WCK3 obtained by compensating for the delay that occurs by passing through the data clock path 204 by the use of the second voltage V2. The second voltage V2 may be lower than the first voltage V1. The second voltage V2 is a minimum operating voltage of VDD2H specified in the JEDEC specification, and may be, for example, but not limited to, about 0.9 V. Because the second voltage V2 is lower than the first voltage V1, a larger delay may occur when the first data clock WCK1, which is an input clock, is transmitted through the data clock path 204.

The method for calibration (S100) includes outputting a second pulse on the basis of the first and third data clocks (S150). For example, the comparison circuit 211 may receive the first and third data clocks WCK1 and WCK3, and output a second pulse PULSE2 on the basis of the first and third data clocks WCK1 and WCK3. The second pulse PULSE2 may be a pulse that is output by performing the AND computation on a signal obtained by inverting the third data clock WCK3 and the first data clock WCK1. The second pulse PULSE2 may be a pulse that is in a logic-high state during a period (e.g., t3 and t4) at which the first data clock WCK1 is delayed, and is in a logic-low state otherwise. The first pulse PULSE1 may be a pulse that is in a logic-high state while the first data clock WCK1 is in a logic-high state and the third data clock WKK3 is in a logic-low state, and is in a logic-low state otherwise. Since the second voltage V2 is lower than the first voltage V1, the duty cycle DC_PULSE2 of the second pulse PULSE2 may be larger than the duty cycle DC_PULSE1 of the first pulse PULSE1.

The method for calibration (S100) includes updating the calibration signal on the basis of the reference voltage and the second pulse (S160). For example, the duty cycle monitor 213 may receive a reference voltage VREF_UP according to the updated control signal R_CODE_UP from the reference voltage generation circuit 212, and receive the second pulse PULSE2 from the comparison circuit 211. The duty cycle monitor 213 may compare the magnitude of the received reference voltage VREF_UP with the duty cycle DC_PULSE2 of the second pulse PULSE2, and output a second comparison signal CS2 corresponding to the comparison result. The control logic circuit 201 may receive the second comparison signal CS2, and update the calibration signal CAL_CODE on the basis of the second comparison signal CS2. At this time, the control logic circuit 201 may update the calibration signal CAL_CODE so that the magnitude of the reference voltage VREF_UP generated on the basis of the updated control signal R_CODE_UP is equal to the duty cycle DC_PULSE2 of the second pulse PULSE2 or is greater than the duty cycle DC_PULSE2 of the second pulse PULSE2. A method for updating the calibration signal CAL_CODE will be described below.

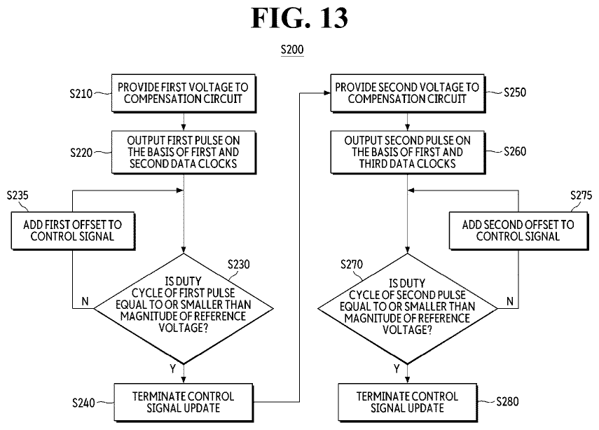

FIG. 13 is a flowchart of the method for calibration according to some embodiments. The update methods of FIG. 8 will be described in FIG. 13 through specific examples. The update method described in FIG. 13 is merely an example, and the embodiments are not limited thereto. The repeated contents described in FIG. 8 will not be provided in FIG. 13.

Referring to FIGS. 1 to 13, the method for calibration (S200) includes supplying a first voltage to the compensation circuit (S210). For example, the data clock path 204 receives a first data clock WCK1 and a first voltage V1, and the compensation circuit 206 may output a second data clock WCK2 obtained by compensating for a delay that occurs by passing through the data clock path 204, by the use of the first voltage V1.

The method for calibration (S200) includes outputting the first pulse on the basis of the first and second data clocks (S220). For example, the comparison circuit 211 may receive the first data clock WCK1 and the second data clock WCK2, and output a first pulse PULSE1 on the basis of the first data clock WCK1 and the second data clock WCK2.

The method for calibration (S200) includes determining whether the magnitude of the reference voltage is equal to or greater than the duty cycle of the first pulse (S230). For example, the duty cycle monitor 213 receives the reference voltage VREF according to the control signal R_CODE from the reference voltage generation circuit 212, and may receive the first pulse PULSE1 from the comparison circuit 211. The duty cycle monitor 213 may compare the magnitude of the received reference voltage VREF with the duty cycle DC_PULSE1 of the first pulse PULSE1, and output a first comparison signal CS1 corresponding to the comparison result. Initially, the control signal R_CODE may be in an initialized state. With the initialized control signal R_CODE, the reference voltage generation circuit 212 may output, for example, 0V as the reference voltage VREF. Since the duty cycle DC_PULSE1 of the first pulse PULSE1 is greater than the magnitude of the current reference voltage VREF, the first comparison signal CS1 which is output by the duty cycle monitor 213 may maintain a logic-low state.

The control logic circuit 201 receives the first comparison signal CS1, and when the first comparison signal CS1 is in a logic-low state, that is, when the magnitude of the reference voltage output by the reference voltage generation circuit 212 is less than the duty cycle DC_PULSE1 of the first pulse PULSE1 (S230-N), the method for calibration (S200) includes updating the control signal R_CODE by adding a first offset to the control signal R_CODE (S235). The control signal R_CODE may be, for example, a digital code of n bits (n is a natural number), and the first offset may be, for example, but not limited to, 1. If the resistance ratio of the reference voltage generation circuit 212 is set, for example, as a value obtained by dividing the magnitude of the second resistor R2 by the magnitude of the first resistor R1, the larger the code value of the control signal R_CODE is, the greater the resistance ratio of the reference voltage generation circuit 212 is, and the greater the magnitude of the reference voltage VREF output by the reference voltage generation circuit 212 may be. The first comparison signal CS1 output by the duty cycle monitor 213 maintains logic-low, and then may change to logic-high at a specific moment, as the magnitude of the reference voltage VREF output by the reference voltage generation circuit 212 increases. The control logic circuit 201 may repeatedly add the first offset to the control signal R_CODE, until the first comparison signal CS1 changes to logic-high, that is, until the magnitude of the reference voltage output by the reference voltage generation circuit 212 becomes greater than or equal to the duty cycle DC_PULSE1 of the first pulse PULSE1.

If the magnitude of the reference voltage output by the reference voltage generation circuit 212 is equal to or greater than the duty cycle of the first pulse PULSE1 (S230-Y), the method for calibration (S200) includes terminating the update of the control signal R_CODE. The updated control signal R_CODE_UP may be stored, for example, in a register of the control logic circuit 201.

The method for calibration (S200) includes providing a second voltage to the compensation circuit (S250). For example, the data clock path 204 receives the first data clock WCK1 and the second voltage V2, and the compensation circuit 206 may output a third data clock WCK3 obtained by compensating for a delay that occurs by passing through the data clock path 204 by the use of the second voltage V2.

The method for calibration (S200) includes outputting the second pulse on the basis of the first and third data clocks (S260). For example, the comparison circuit 211 may receive the first data clock WCK1 and the third data clock WCK3, and output a second pulse PULSE2 on the basis of the first data clock WCK1 and the third data clock WCK3.

The method for calibration (S200) includes determining whether the magnitude of the reference voltage is equal to or greater than the duty cycle of the second pulse (S270). For example, the duty cycle monitor 213 may receive a reference voltage VREF_UP according to an updated control signal R_CODE_UP from the reference voltage generation circuit 212, and receive the second pulse PULSE2 from the comparison circuit 211. The duty cycle monitor 213 may compare the magnitude of the received reference voltage VREF_UP with a duty cycle DC_PULSE2 of the second pulse PULSE2, and output a second comparison signal CS2 corresponding to the comparison result. The reference voltage VREF_UP according to the updated control signal R_CODE_UP may be equal to or greater than the duty cycle DC_PULSE1 of the first pulse PULSE1, but may be smaller than (i.e., less than) the duty cycle DC_PULSE2 of the second pulse PULSE2. Since the duty cycle DC_PULSE2 of the second pulse PULSE2 is greater than the magnitude of the reference voltage VREF_UP, the second comparison signal CS2 output by the duty cycle monitor 213 may maintain a logic-low state.

The control logic circuit 201 receives the second comparison signal CS2, and when the second comparison signal CS2 is in a logic-low state, that is, when the magnitude of the reference voltage VREF_UP output by the reference voltage generation circuit 212 is less than the duty cycle of the second pulse PULSE2 (S270-N), the method for calibration (S200) includes updating the calibration signal CAL_CODE by adding a second offset to the calibration signal CAL_CODE (S275). The calibration signal CAL_CODE may be, for example, a digital code of m-bits (m is a natural number) or a voltage having a specific magnitude. The second offset may be, for example, 1 when the calibration signal CAL_CODE is a digital code, or may be, for example, 0.1 V when the calibration signal CAL_CODE is a voltage having a specific magnitude, but is not limited thereto. As the magnitude of the calibration signal CAL_CODE increases, the difference in the compensation amount according to the magnitude of the power supply voltage received by the compensation circuit 206 may also increase. As the magnitude of the calibration signal CAL_CODE increases, the delay of the data clock decreases, and the duty cycle DC_PULSE2 of the second pulse PULSE2 may decrease. The second comparison signal CS2 that is output by the duty cycle monitor 213 maintains logic-low, and then may change to logic-high at a specific moment as the duty cycle DC_PULSE2 of the second pulse PULSE2 decreases. The control logic circuit 201 may repeatedly add the second offset to the calibration signal CAL_CODE, until the second comparison signal CS2 changes to logic-high, that is, until the magnitude of the reference voltage VREF_UP that is output by the reference voltage generation circuit 212 becomes equal to or greater than the duty cycle of the second pulse PULSE2.

When the magnitude of the reference voltage that is output by the reference voltage generation circuit 212 is equal to or greater than the duty cycle of the second pulse PULSE2 (S270-Y), the method for calibration (S200) includes terminating the update of the calibration signal CAL_CODE (S280). The updated calibration signal CAL_CODE may be stored, for example, in a register of the control logic circuit 201.

According to some embodiments, the duty cycle values DC_PULSE1 and DC_PULSE2 of the first pulse PULSE1 and the second pulse PULSE2 may be identical or may have a small difference that is enough to be recognized as being identical. When the duty cycle values DC_PULSE1 and DC_PULSE2 of the first pulse PULSE1 and the second pulse PULSE2 are identical or have a small difference that is enough to be recognized as being identical, the delay difference of the data clock due to voltage fluctuations (e.g., tWCK2DQI_volt specified in the JEDEC specifications) may be ideally eliminated (e.g., tWCK2DQI_volt=0).

According to some embodiments, a magnitude of an appropriate calibration signal to be input to a memory device on which the method is to be performed may be obtained by the above method. Because the magnitude of the appropriate calibration signal may be obtained according to the sensitivity to the voltage for each memory device by the above method, it is possible to reduce the variation of difference in delays (e.g., tWCK2DQI_volt) due to voltage fluctuations for each memory device.

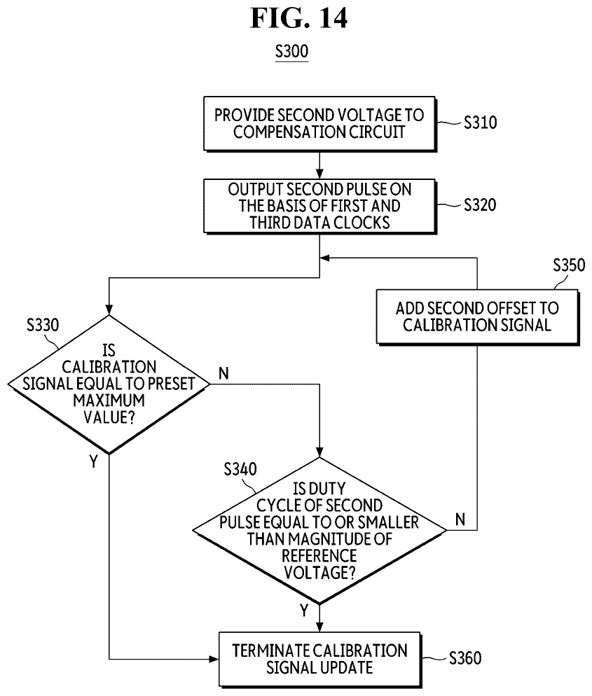

FIG. 14 is a flowchart of a method for calibration according to some embodiments. A specific example of the update method of FIG. 8 will be described in FIG. 14. The update method described in FIG. 14 is only an example, and the embodiment is not limited thereto. The repeated description of the contents of FIGS. 8 and 13 will not be provided in FIG. 14.

Referring to FIGS. 1 to 14, the method for calibration (S300) includes supplying a second voltage to the compensation circuit (S310). For example, when the update of the control signal R_CODE is terminated, the data clock path 204 receives the first data clock WCK1 and the second voltage V2, and the compensation circuit 206 may output a third data clock WCK3 obtained by compensating for the delay that occurs by passing through the data clock path 204, by the use of the second voltage V2.

The method for calibration (S300) includes outputting a second pulse on the basis of the first and third data clocks (S320). For example, the comparison circuit 211 may receive the first data clock WCK1 and the third data clock WCK3, and output a second pulse PULSE2 on the basis of the first data clock WCK1 and the third data clock WCK3.

The method for calibration (S300) includes determining whether the calibration signal is a preset maximum value (S330). If the current calibration signal CAL_CODE reaches the preset maximum value, the second offset may no longer be added to the calibration signal CAL_CODE. If the calibration signal CAL_CODE reaches the preset maximum value (S330-Y), the method for calibration (S300) includes terminating the update of the calibration signal (S360). If the calibration signal CAL_CODE does not reach the preset maximum value (S330-N), the operation S340 may be performed.

The method for calibration (S300) includes determining whether the magnitude of the reference voltage is equal to or greater than the duty cycle of the second pulse (S340). For example, the duty cycle monitor 213 may receive a reference voltage VREF_UP according to the updated control signal R_CODE_UP from the reference voltage generation circuit 212, and receive a second pulse PULSE2 from the comparison circuit 211. The duty cycle monitor 213 may compare the magnitude of the received reference voltage VREF_UP with the duty cycle DC_PULSE2 of the second pulse PULSE2, and output a second comparison signal CS2 corresponding to the comparison result.

The control logic circuit 201 receives the second comparison signal CS2, and if the second comparison signal CS2 is in a logic-low state, that is, when the magnitude of the reference voltage output by the reference voltage generation circuit 212 is smaller than (i.e., less than) the duty cycle of the second pulse PULSE2 (S340-N), the method for calibration (S300) includes updating the calibration signal CAL_CODE by adding a second offset to the calibration signal CAL_CODE (S350). The control logic circuit 201 may repeatedly add the second offset to the calibration signal CAL_CODE, until the second comparison signal CS2 changes to logic-high, that is, until the magnitude of the reference voltage VREF_UP output by the reference voltage generation circuit 212 becomes greater than or equal to the duty cycle DC_PULSE2 of the second pulse PULSE2. At this time, after adding the second offset to the calibration signal CAL_CODE, it is determined whether the calibration signal CAL_CODE has reached a preset maximum value, and if the calibration signal CAL_CODE has reached the preset maximum value, the updating of the calibration signal CAL_CODE may be terminated.

If the magnitude of the reference voltage VREF_UP output by the reference voltage generation circuit 212 is equal to or greater than the duty cycle DC_PULSE2 of the second pulse PULSE2 (S340-Y), the method for calibration (S300) includes terminating the updating of the calibration signal CAL_CODE (S360). The updated calibration signal CAL_CODE may be stored, for example, in a register of the control logic circuit 201.

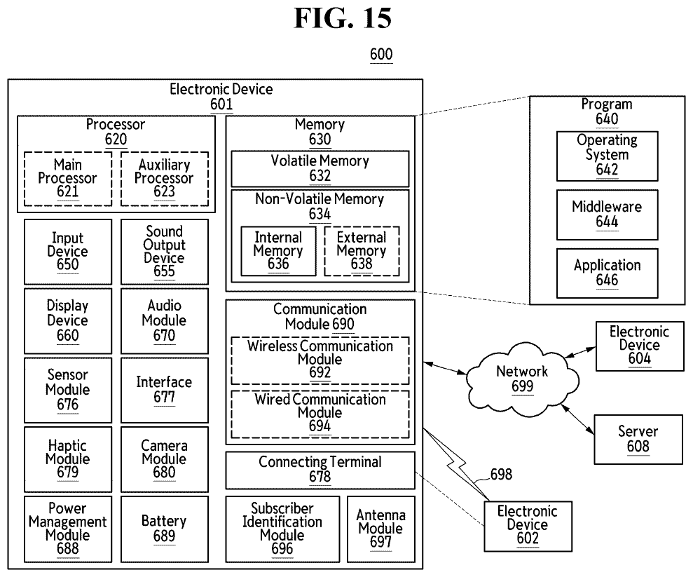

FIG. 15 is a block diagram of an electronic device including a memory device to which the calibration circuit according to some embodiments is applied.

Referring to FIG. 15, an electronic device 601 inside a network environment 600 may communicate with an electronic device 602, for example, through a first network 698 such as a short-range wireless network, or may communicate with an electronic device 604 or a server 608, for example, through a second network 699 such as a long-range wireless network. In some embodiments, although such an electronic device 601 may be, for example, a notebook computer, a laptop computer, a portable mobile terminal, or the like, the embodiments are not limited thereto.

The electronic device 601 may communicate with the electronic device 604 through the server 608. The electronic device 601 may include a processor 620, a memory 630, an input device 650, a sound output device 655, an image display device 660, an audio module 670, a sensor module 676, an interface 677, a haptic module 679, a camera module 680, a power management module 688, a battery 689, a communication module 690, a subscriber identification module (SIM) 696, an antenna module 697, and the like.

In some embodiments, at least one of the components, for example, such as the display device 660 or the camera module 680, may be omitted from the electronic device 601, or one or more other components may be added to the electronic device.

Some of the components may be implemented as a single integrated circuit (IC). For example, the sensor module 676, such as a fingerprint sensor, an iris sensor or an illuminance sensor, may be buried in an image display device such as a display.

The processor 620 may execute software (e.g., program 640) for controlling other components of at least one electronic device 601, such as hardware or software component connected to the processor 620, thereby performing various date processes and computations.

As at least a part of data processes or computations, the processor 620 may load command or data received from other components such as the sensor module 676 or the communication module 690 to a volatile memory 632, process the command or data stored in the volatile memory 632, and store the resultant data in a non-volatile memory 634.

The processor 620 may include, for example, a main processor 621 such as a central processing unit (CPU) or an application processor (AP), and an auxiliary processor 623 that operates independently of the main processor 621 or operates in connection with the main processor 621.

Such an auxiliary processor 623 may include, for example, a graphic processing unit (GPU), an image signal processor (ISP), a sensor hub processor, a communication processor (CP) or the like.

The auxiliary processor 623 may be configured to consume less power than the main processor 621 or perform specific functions. The auxiliary processor 623 may be implemented separately from the main processor 621 or as a part thereof.

The auxiliary processor 623 may control at least some of the functions or statuses associated with at least one component among the components of the electronic device 601, for example, on behalf of the main processor 621 while the main processor 621 is in an inactive status, or along with the main processor 621 while the main processor 621 is in an active status.

The memory 630 may store various types of data used in at least one component of the electronic device 601. The various types of data may include, for example, input data and output data for software such as program 640, and commands associated therewith. The memory 630 may include the volatile memory 632 and the non-volatile memory 634.

The program 640 may be stored as software in the memory 630, and may include, for example, an operating system (OS) 642, a middleware 644 or an application 646.

The input device 650 may receive commands or data to be used in other components of the electronic device 601 from the outside of the electronic device 601. The input device 650 may include, for example, a microphone, a mouse or a keyboard.

The sound output device 655 may output a sound signal to the outside of the electronic device 601. The sound output device 655 may include, for example, a speaker. Multimedia data may be output through the speaker.

The image display device 660 may visually provide information to the outside of the electronic device 601. The image display device may include, for example, a display, a hologram device or a projector, and a control circuit for controlling the corresponding one among the display, the hologram device or the projector.

The image display device 660 may include a touch circuit configured to detect the touch, or a sensor circuit, for example, such as a pressure sensor configured to measure strength of force caused by the touch.

The audio module 670 may convert the sound into an electrical signal or vice versa. In some embodiments, the audio module 670 may obtain the sound through the input device 650 or may output the sound through the sound output device 655 or through a headphone of the external electronic device 602 that is directly or wirelessly connected to the electronic device.

The sensor module 676 detects an operating status of the electronic device 601, for example, such as power or temperature, or an external environmental status of the electronic device 601, for example, such as a user's status, and may generate an electrical signal or data value corresponding to the detected status. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor or an illuminance sensor.

The interface 677 may support one or more specified protocols to be used by the electronic device 601 connected to the external electronic device 602 directly or wirelessly. In some embodiments, the interface 677 may include, for example, a high-resolution multimedia interface (HDMI), a universal serial bus (USB) interface, a secure digital (SD) card interface or an audio interface.

A connecting terminal 678 may include a connector through which the electronic device 601 may be physically connected to the external electronic device 602. In some embodiments, the connecting terminal 678 may include, for example, an HDMI connector, a USB connector, an SD card connector or an audio connector (e.g., a headphone connector or the like).

The haptic module 679 may convert an electrical signal into a mechanical stimulus, for example, such as vibration or motion that may be perceived by the user through a tactile sensation or a kinesthetic sensation. In some embodiments, the haptic module 679 may include, for example, a motor, a piezoelectric element or an electrical stimulator.

The camera module 680 may capture still images or moving images. In some embodiments, the camera module 680 may include one or more lenses, an image sensor, an image signal processor, a flash, and the like.

The battery 689 may supply power to at least one component of the electronic device 601. According to some embodiments, the battery 689 may include, for example, a non-rechargeable primary battery, a rechargeable secondary battery or a fuel cell.

The power management module 688 may manage the power to be supplied to the electronic device 601. The power management module 688 may be implemented, for example, as at least a part of a power management integrated circuit (PMIC).

The communication module 690 may support establishment of direct communication channel or wireless communication channel between the electronic device 601 and an external electronic device, for example, such as the electronic device 602, the electronic device 604 or the server 608, and may perform communication through the established communication channel.

The communication module 690 may include one or more communication processors that is operable independently of the processor 620 and supports a direct communication or a wireless communication.

The communication module 690 may include a wireless communication module 692, for example, such as a cellular communication module, a short-range wireless communication module or a global navigation satellite system (GNSS) communication module, or a wired communication module 694, for example, such as a local area network (LAN) communication module or a power line communication module (PLC).

Among these communication modules, the corresponding communication module may communicate with the external electronic device through the first network 698, for example, such as a Bluetooth™, a WiFi (wireless-fidelity) direct or an IrDA (standard of the Infrared Data Association) or the second network 699, for example, such as a cellular communication network, an Internet or a long-range communication network

The various types of communication modules may be implemented as a single component or may be implemented as a plurality of components separated from each other. The wireless communication module 692 may verify and authenticate the electronic device 601 inside a communication network, such as the first network 698 or the second network 699, for example, using subscriber information such as an international mobile subscriber identifier (IMSI) stored in the subscriber identification module 696.

The antenna module 697 may transmit or receive signals or power to and from the outside of the electronic device 601. In some embodiments, the antenna module 697 may include one or more antennas, and hence, at least one antenna which is suitable for communication scheme used in communication networks such as the first network 698 or the second network 699 may be selected by the communication module 690. The signal or power may then be transmitted or received between the communication module and the external electronic device through at least one selected antenna.

At least some of the aforementioned components may be connected to each other to perform signal communication between them through an inter-peripheral communication scheme, for example, such as a general purpose input and output (GPIO), a serial peripheral interface (SPI) or a mobile industry processor interface (MIPI).

The command or data may be transmitted or received between the electronic device 601 and the external electronic device 606 through the server 608 connected to the second network 699. Each of the electronic devices 602 and 606 may be devices which are the same type as or different type from of the electronic device 601. All or some of the operations to be executed in the electronic device 601 may be executed in one or more external electronic devices 602, 606 or 608. For example, all or some of the operations to be executed in the electronic device 601 may be performed in one or more external electronic devices 602, 606 or 608.

For example, if the electronic device 601 needs to perform the functions or services automatically or in response to request from a user or other devices, the electronic device 601 that executes the functions or services may require one or more external electronic devices to perform at least some of the functions or services on behalf of this or additionally. One or more external electronic devices that receive the request may perform at least some of the requested function or service or additional functions or additional services associated with the request, and send the results of the execution to the electronic device 601. The electronic device 601 provides the results as at least part of the response to the request, with or without accompanying further processing of the results. For example, cloud computing, distributed computing or client-server computing techniques may be used for this purpose.

According to some embodiments, the memory 630 may include the memory device 20 of FIG. 1. The memory 630 may include a data clock path and a calibration circuit. The memory 630 may perform the method for calibration described in FIGS. 1 to 14. The memory 630 may be supplied with a power supply voltage, for example, from the power management module 688, the battery 689, or the like. The memory 630 may be supplied with a data clock, for example, from the processor 620. The data clock path of the memory 630 may, for example, receive a first data clock and a first voltage, and output a second data clock. Also, the data clock path of the memory 630 may receive the first data clock and a second voltage having a smaller size than the first voltage (i.e., a second voltage that is less than the first voltage), and output a third data clock. The calibration circuit of the memory 630 may, for example, determine a calibration signal to be input to the data clock path of the memory 630 on the basis of the first data clock, the second data clock, and the third data clock. The data clock path of the memory 630 may receive the determined calibration signal, and output a data clock signal from which a difference in delays due to fluctuations in the power supply voltage have been removed.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Although some embodiments of the present disclosure have been described above with reference to the accompanying diagrams, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

1. A method for calibration comprising:
outputting a second data clock obtained by compensating for a first data clock based on a calibration signal and a first voltage;
outputting a first pulse based on the first and second data clocks;
updating a control signal based on a reference voltage and the first pulse, wherein the reference voltage is generated based on the control signal;
outputting a third data clock obtained by compensating for the first data clock based on the calibration signal and a second voltage that is less than the first voltage;
outputting a second pulse based on the first and third data clocks; and
updating the calibration signal based on the reference voltage generated based on the control signal that was updated and the second pulse.

2. The method for calibration of claim 1,
wherein the outputting of the first pulse based on the first and second data clocks comprises:
outputting the first pulse by performing an AND computation on the first data clock and an inverting of the second data clock.

3. The method for calibration of claim 1,
wherein the outputting of the first pulse based on the first and second data clocks comprises:
outputting the first pulse at a logic-high voltage during a first time period at which the first data clock is at a logic-high voltage and the second data clock is at a logic-low voltage.

4. The method for calibration of claim 1,
wherein the updating of the control signal based on the reference voltage and the first pulse comprises:
updating the control signal such that a magnitude of the reference voltage generated based on the control signal that was updated is equal to or greater than a duty cycle of the first pulse.

5. The method for calibration of claim 1,
wherein the updating of the control signal based on the reference voltage and the first pulse comprises:
updating the control signal by repeatedly adding a first offset to the control signal until a magnitude of the reference voltage generated based on the control signal is equal to or greater than a duty cycle of the first pulse.

6. The method for calibration of claim 1,
wherein the updating of the calibration signal based on the reference voltage and the second pulse comprises:
updating the calibration signal such that a magnitude of the reference voltage generated based on the control signal that was updated is equal to or greater than a duty cycle of the second pulse.

7. The method for calibration of claim 1,
wherein the updating of the calibration signal based on the reference voltage and the second pulse comprises:
updating the calibration signal by repeatedly adding a second offset to the calibration signal, until a magnitude of the reference voltage is greater than or equal to a duty cycle of the second pulse.

8. The method for calibration of claim 1,
wherein the updating of the calibration signal based on the reference voltage generated based on the control signal that was updated and the second pulse comprises:
updating the calibration signal by repeatedly adding a second offset to the calibration signal, until the calibration signal that was updated has a preset maximum value.

9. The method for calibration of claim 1,
wherein the reference voltage is generated by adjusting a resistance ratio of first and second resistors of a reference voltage generation circuit in accordance with the control signal.

10. The method for calibration of claim 1, further comprising:
initializing the calibration signal and the control signal.

11. An integrated circuit comprising:
a data clock path circuit that is configured to receive a first voltage, a first data clock, and a calibration signal, and configured to compensate for a delay of the first data clock using the first voltage in accordance with the calibration signal to output a second data clock;
a comparison circuit configured to output a first pulse based on the first data clock and the second data clock;
a reference voltage generation circuit configured to receive a control signal, and configured to output a reference voltage in accordance with the control signal; and
a duty cycle monitor configured to compare a magnitude of the reference voltage with a duty cycle of the first pulse, and configured to output a first comparison signal corresponding to a result of comparing the magnitude of the reference voltage with the duty cycle of the first pulse.

12. The integrated circuit of claim 11,
wherein the comparison circuit is configured to perform an AND computation on the first data clock and an inverting of the second data clock to output the first pulse.

13. The integrated circuit of claim 11,
wherein the comparison circuit is configured to output the first pulse that is a logic-high voltage during a first time interval at which the first data clock is at a logic-high voltage and the second data clock is at a logic-low voltage.

14. The integrated circuit of claim 11,
wherein the reference voltage generation circuit comprises first and second resistors, and is configured to adjust a resistance ratio of the first and the second resistors in accordance with the control signal to output the reference voltage.

15. The integrated circuit of claim 14,
wherein the reference voltage generation circuit adjusts a magnitude of the first resistor in accordance with the control signal to adjust the resistance ratio of the first and the second resistors.

16. The integrated circuit of claim 11, further comprising:
a control logic circuit configured to update the control signal based on the first comparison signal.

17. The integrated circuit of claim 16,
wherein the control logic circuit is configured to update the control signal such that the magnitude of the reference voltage generated based on the control signal that was updated is equal to or greater than a duty cycle of the first pulse.

18. The integrated circuit of claim 16,
wherein the control logic circuit is configured to update the control signal by repeatedly adding a first offset to the control signal until a logical value of the first comparison signal changes.

19. The integrated circuit of claim 16,
wherein the control logic circuit is configured to update the control signal by repeatedly adding a first offset to the control signal, until the magnitude of the reference voltage generated based on the control signal that was updated becomes greater than or equal to the duty cycle of the first pulse.

20. A memory device comprising:
a memory cell array configured to store data;
a data clock path circuit configured to output a second data clock based on a first data clock and a first voltage, and configured to output a third data clock based on the first data clock and a second voltage less than the first voltage;
a calibration circuit configured to determine a calibration signal based on the first, second and third data clocks; and
a control logic circuit configured to provide the calibration signal to the data clock path circuit,
wherein the data clock path circuit is configured to output a fourth data clock based on the first data clock and the calibration signal, and
wherein the control logic circuit is configured to write data to the memory cell array, using the fourth data clock.
